(19) United States
(12) Patent Application Publication
(10) Pub. No.: US 2008/0088722 A1
(43) Pub. Date: Apr. 17, 2008

(54) Photoelectric converter

(75) Inventor: Yoshimasa Takeichi, Gifu (JP)

Correspondence Address: OLIFF & BERRIDGE, PLC, P.O. BOX 320850, ALEXANDRIA, VA, 22320-4850, US

(73) Assignees: SANYO ELECTRIC CO., LTD., MORIGUCHI-SHI (JP); SANYO SEMICONDUCTOR CO., LTD., Ora-Gun (JP)

(21) Appl. No.: 11/907,224

(22) Filed: Oct. 10, 2007

(30) Foreign Application Priority Data
Oct. 13, 2006 (JP) 2006-280493

(51) Int. Cl. H04N 5/335

(52) U.S. Cl. 348/273; 348/E05.081

(57) ABSTRACT

A photoelectric converter comprising a resin layer that absorbs infrared light cuts out unnecessary infrared light, while the photoelectric converter has a problem that the resin layer also reduces the transmission of light in the visible range. A photoelectric converter improving the problem comprises a semiconductor substrate (2) on which photoelectric conversion elements are formed, a color filter (8) provided on the semiconductor substrate (2), and a support base (21) bonded to the color filter (8), wherein an interference filter (11) comprised of multiple thin layers of dielectric material laminated together and reflecting infrared light is provided to the support base (21). As a result, light attenuation can be minimized while infrared light is cut, and the usage efficiency of light can be increased. A photoelectric converter adjusted to the luminous efficiency of the human eye can be obtained by adjusting the light transmittance characteristics of the color filter (8) to the luminous efficiency of the human eye.

### CROSS-REFERENCE TO RELATED APPLICATION

The priority application number JP2006-280493 upon which this patent application is based is hereby incorporated by the reference.

### BACKGROUND OF THE INVENTION

1. Field of the Invention

This invention relates to a photoelectric converter that uses a wavelength selection filter to adjust the wavelength characteristics, and particularly to an illuminance sensor that has wavelength characteristics based upon the luminosity curve for humans.

2. Description of the Related Art

In recent years, chip-sized packages (CSP) having wiring drawn out from the sides of an element have been used to miniaturize photoelectric converters that include a photoelectric conversion element.

FIG. 1 shows a cross-section of a conventional photoelectric converter 200 with a CSP. A semiconductor substrate 30 is designed with a resin layer 46 on top of a lower support base 44. A semiconductor integrated circuit 32 including a photoelectric conversion element is formed on the surface of the semiconductor substrate 30. A color filter 34, which is a filter for visible light, is formed so that a portion of the photoelectric conversion element formed on the semiconductor substrate 30 is covered. An internal wiring 36 connected to the semiconductor integrated circuit 32 is formed on the substrate surface 30. The internal wiring 36 is connected to the wiring in the semiconductor integrated circuit 32 via a connector hole set up in the oxide film or other insulating film, and plays a role as an electrical connection between the semiconductor integrated circuit 32 and the exterior.

A smoothing film 38 is provided to the surface of the semiconductor substrate 30 having the color filter 34 and the internal wiring 36, and is used to smooth irregularities on the surface. The smoothing film 38 can be formed with epoxy or another resin as the primary constituent.

An upper support base 42 is bonded to the surface of the smoothed semiconductor substrate 30 by using a resin layer 40. A lower support base 44 is bonded to the underside of the semiconductor substrate 30 by using a resin layer 46. The upper support base 42 and the lower support base 44 fulfill the role of increasing the structural strength of the photoelectric converter.

A conductive external wiring 48 is set up so as to be connected to an end part of the internal wiring 36 from the side of the semiconductor substrate 30 to the lower support base 44. A solder ball 54 and the internal wiring 36 provided to the lower surface of the lower support base 44 are connected via the external wiring 48. The solder ball 54 is arranged on the buffer material 52 which is set up to reduce the stress from the lower support base 44. The surface of the lower support base 44 with the external wiring 48 is covered with a protective film 50 to prevent corrosion.

FIG. 2 shows a cross-section of the upper portion of the photoelectric converter 200. The structure of the color filter 34 and the support base 42 provided to the semiconductor substrate 30 are described with reference to FIG. 2.

The ordinary color filters 34a and 34b having wavelength regions for red (R), blue (B), and green (G) as the transparent regions are formed on the semiconductor substrate 30. For instance, the color filter 34 for a CCD solid-state image sensor is in the form of a plurality of rectangles or stripes based on the pixels.

FIG. 3 shows the sensitivity characteristics for the photoelectric conversion element when an ordinary color filter in a CCD solid-state imaging element is mounted on the photoelectric conversion element. The horizontal axis shows the wavelength of the light reaching the filter, and the vertical axis shows the sensitivity at each wavelength. In FIG. 3, the characteristics for when a color filter corresponding to the wavelength region for red (R) are shown by curve A, the characteristics for when a color filter corresponding to the wavelength region for green (G) are shown by curve B, and the characteristics for when a color filter corresponding to the wavelength region for blue (B) are shown by curve C. A typical example of sensitivity for a wavelength in a photoelectric conversion element (without a color filter) formed on a silicon substrate is shown by curve D.

The smoothing film 38 is formed on the color filter 34, and the upper support base 42 is provided to the adhesive resin layer 40. The upper support base 42 is formed by having several bases 42a being glass or otherwise transparent bonded using the resin layer 42b. The resin layer 42b comprises a material that includes a substance that absorbs infrared light. For instance, the resin layer 42b comprises a material obtained by admixing a metallic complex having bivalent copper ions with an epoxy or the like.

The photoelectric conversion element made of silicon is sensitive even with infrared light of 700 nm or greater. The ordinary color filter 34 has a relatively high transmittance even in the infrared region, in addition to the various wavelength regions (red, blue, green). Consequently, as was described above, the photoelectric converter 200 can prevent infrared light from reaching the photoelectric conversion element by having the resin layer 42b that has a mixture of materials that absorb infrared light arranged on the upper support base 42.

The technology described above is cited in Japanese Laid-open Patent Application Publication No. 2005-332917.

However, as can be seen in FIG. 1, in a conventional photoelectric converter having a resin layer which absorbs infrared light, the resin layer not only absorbs infrared light, but also greatly reduces transmittance to light in the visible light range, and thus leads to problems of reduced sensitivity.

### SUMMARY OF THE INVENTION

With the foregoing problems of the prior art in view, the present invention provides a photoelectric converter that increases sensitivity while also cutting out infrared light.

The invention is a photoelectric converter comprising a semiconductor substrate on which photoelectric converter elements are formed, a color filter provided on the semiconductor substrate, and a support base bonded to the color filter. The support base has an interference filter that is comprised of multiple thin layers of dielectric material and reflects infrared light.

### BRIEF DESCRIPTION OF THE DRAWINGS

FIG. 1 is a cross-sectional view showing a configuration of a conventional photoelectric converter;

FIG. 2 is a cross-sectional view showing an upper portion of a conventional photoelectric converter;

FIG. 3 is a graph showing the transmittance of an ordinary color filter in a CCD solid-state image sensor;

FIG. 4 is a cross-sectional view showing a configuration of a photoelectric converter in an embodiment of the present invention;

FIG. 5 is a cross-sectional view showing an upper portion of the photoelectric converter in an embodiment of the present invention;

FIG. 6 is a cross-sectional view showing an upper portion of the photoelectric converter in an embodiment of the present invention;

FIGS. 7-11 are cross-sectional views showing the manufacturing process for the photoelectric converter in an embodiment of the present invention;

FIG. 12 is a graph showing the luminosity curve for humans;

FIG. 13 is a graph showing the wavelength dependence of the light transmittance of the interference filter in the present invention; and

FIG. 14 is a graph showing the wavelength dependence of the light transmittance of the color filter in the present invention.

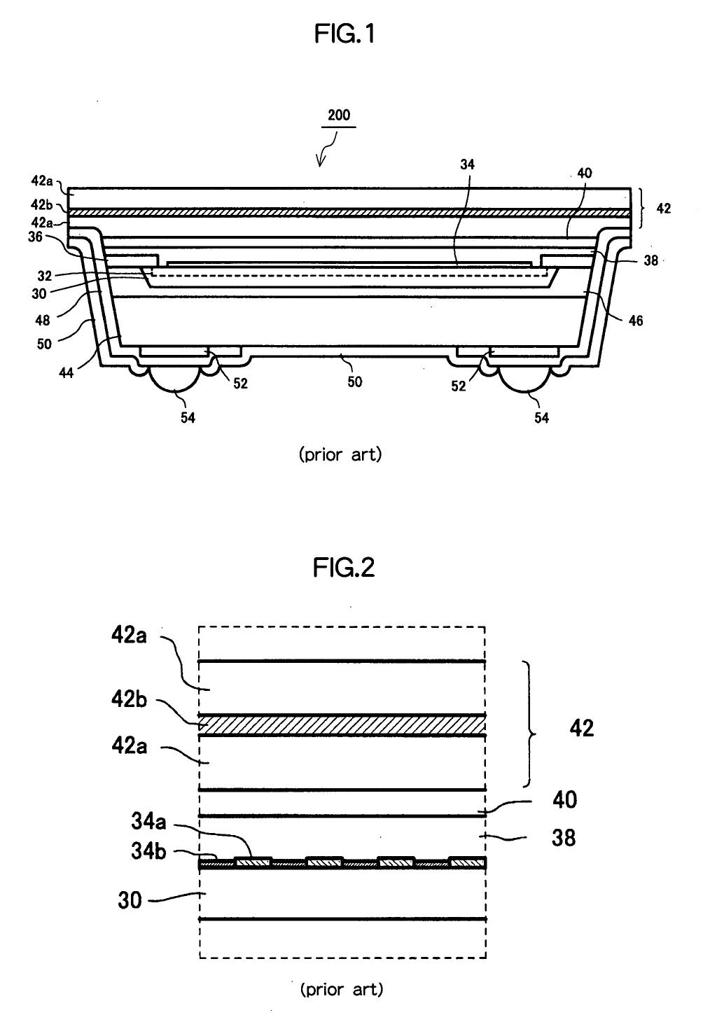

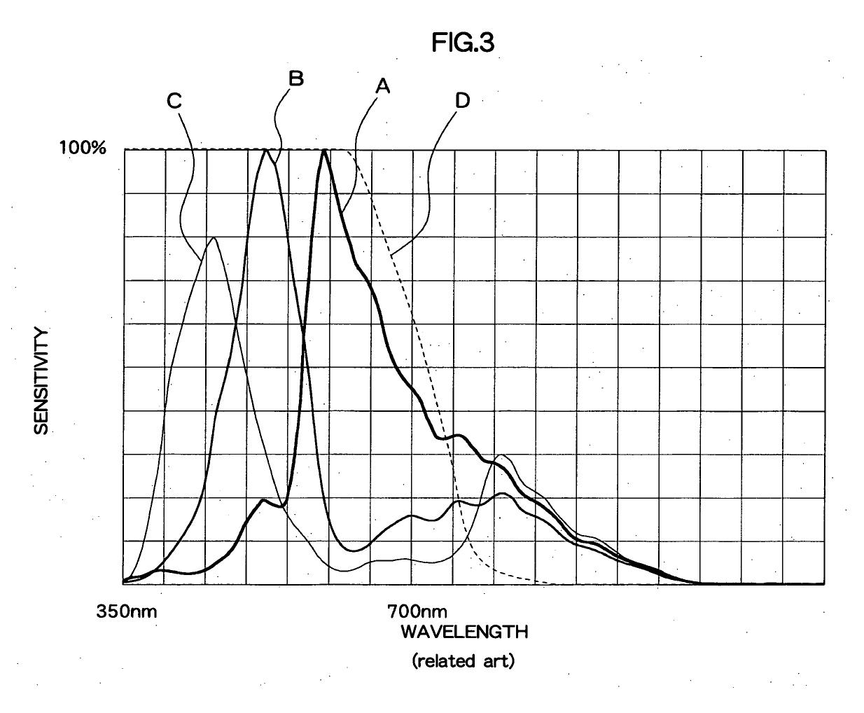

### DETAILED DESCRIPTION OF THE PREFERRED EMBODIMENT

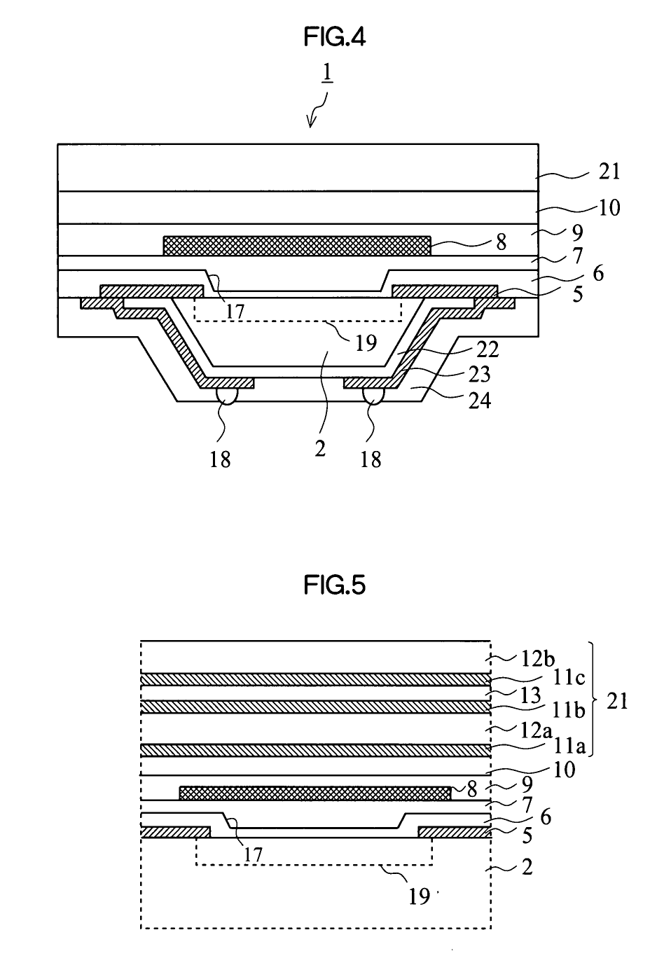

The photoelectric converter in an embodiment of the present invention is described in detail with reference to the drawings. FIG. 4 shows a vertical cross-section of a photoelectric converter 1 according to the present embodiment, which employs a CSP and comprises an optical filter having transmittance characteristics adjusted to the luminous efficiency of human eyes.

A semiconductor integrated circuit 19 made up of photoelectric conversion elements is formed on the surface of a semiconductor substrate 2. For instance, elements comprising PN junctions having impurities added to the N-type on the surface of the P-type semiconductor substrate can be used as the photoelectric conversion elements. It is acceptable to have a photoelectric conversion element comprising a PNP junction having an N well layer having N-type impurities added to the P-type substrate, and having P-type impurities added to the N well layer, and it is also acceptable to have a photoelectric conversion element comprising a PIN junction. A photoelectric conversion element having P-type impurities added to the N-type semiconductor substrate is also acceptable. In other words, the photoelectric conversion element in the invention is not limited to the embodiment shown in FIG. 4; the photoelectric conversion element may also be an element that receives light in the semiconductor substrate and converts the light to an electrical signal.

An internal wiring 5 is provided to the semiconductor substrate 2. The internal wiring 5 fulfills the role of extracting as electrical information the electrons formed by the photoelectric conversion in the semiconductor substrate 2. Here, the internal wiring 5 is shown in typical form as a single-layer structure, but other forms are possible in the invention. For instance, the internal wiring 5 can be formed by a multi-layer wiring structure having two or more layers. The internal wiring 5 can function as a shading film, and can prevent light from reaching the semiconductor substrate 2. A separate shading film can be provided to the same or higher layer than where the internal wiring 5 is present. The shading film can be formed so as to enclose an aperture 17, to be described later.

A first protective film 6 made of silicon oxide (SiO₂) film or silicon nitride (SiN) film is formed on the semiconductor substrate 2 on which the internal wiring 5 is formed. A first protective film 6 has the aperture 17 which corresponds to the region where the photoelectric conversion element on the semiconductor substrate 2 receives light. The aperture 17 does not need to be provided. However, attenuation of light resulting from the first protective film 6 can be reduced if the aperture 17 is provided. The thickness of the first protective film 6 at the aperture 17 can be adjusted, and the interference effect of the multiple layers can be used to block reflected light. As a result, the light usage efficiency can be improved.

A smoothing film 7 which comprises an acrylic or epoxy resin that allows light in the visible range to pass through is formed on the semiconductor substrate 2 where the first protective film 6 is built up. The irregularities on the semiconductor substrate 2 resulting from the internal wiring 5 are smoothed by the smoothing film 7. A color filter 8 having a transmission spectrum adjusted to the luminous efficiency of human eyes is formed on the smoothing film 7. The color filter 8 can be formed in correspondence with the aperture 17, or can be made along the entire surface of the photoelectric converter 1. The adhesiveness of the color filter 8 can be improved by providing the smoothing film 7, which is an organic film, on the first protective film 6, an inorganic film. Peeling of the color filter 8 from the semiconductor substrate 2 can be prevented.

A resin layer 10 comprising an acrylic or epoxy resin transparent to light in the visible range is provided to the color filter 8 with a second protective film 9 comprising an acrylic or epoxy resin interposed therebetween. By providing the second protective film 9 between the color filter 8 and the resin layer 10, the boundary between the color filter 8 and the resin layer 10 can be maintained, and the adhesiveness can be improved.

The semiconductor substrate 2 is joined to the support base 21 via the resin layer 10. The resin layer 10 preferably comprises a material that is transparent to light in the visible range, such as an epoxy resin.

FIG. 5 is a vertical cross-sectional view in which the upper structure of the photoelectric converter 1 for the form of the embodiment has been enlarged. A detailed description of a support base 21 shall be provided with reference to FIG. 5.

The support base 21 has a structure in which glass substrates 12a, 12b, which are transparent to light in the visible range, and interference filters 11a, 11b, 11c, which reflect infrared light, are set up in layers. In concrete terms, the glass substrate 12a having the interference filter 11a, 11b formed on both sides, and the glass substrate 12b having the interference filter 11c formed on only one side, are bonded using the resin layer 13.

The interference filters 11a, 11b, 11c are a multilayer dielectric film in which a plurality of layers of dielectric thin films are built up through the use of electron-beam deposition, ion-assisted deposition, or ion-plating film formation. A metallic oxide film comprising Ti or Si should be used for the dielectric. Light in the infrared range is incident on the photoelectric converter 1, and is reflected by the multilayer interference in the multilayer dielectric film. The light outside the infrared range is allowed to pass through. Through the use of the interference filter 11, which cuts off infrared light with multilayer interference, the light usage efficiency is significantly improved over that of the conventional photoelectric converter 200 with a resin that absorbs infrared light. Only the light wavelengths required are extracted by the interference filter 11 comprising a multilayer dielectric film. In other words, the wavelength selectivity is improved. In the present embodiment, a plurality of interference filters 11a, 11b, 11c are built up, and as a result, infrared light can be reliably cut.

In the present embodiment, the resin layers 10, 13 are composed of a material that is transparent to visible light and infrared light. However, a material that absorbs infrared light may be added. For instance, a bivalent copper ion metallic complex is ideally used as a material for absorbing infrared light.

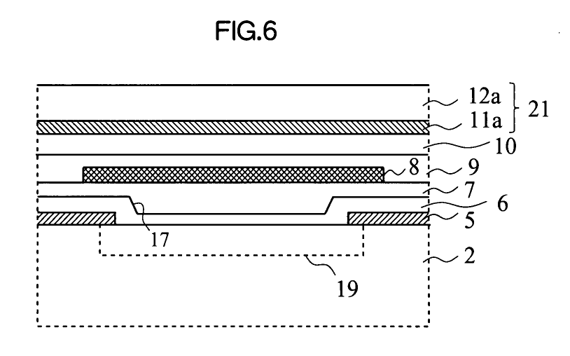

In the present embodiment, the support base 21 has a multilayer structure comprising the interference filters 11a, 11b, 11c, and the glass substrates 12a, 12b. However, this structure is not provided by way of limitation in the invention. For instance, as shown in FIG. 6, the support base 21 can be composed of one interference filter 11a and one glass substrate 12a. The support base 21 can be composed of the glass substrate 12a, the interference filter 11b, the resin layer 13, and the glass substrate 12b, in the stated order starting from the resin layer 10. In other words, the composition of the interference filter 11 and the glass substrate 12 can be easily changed.

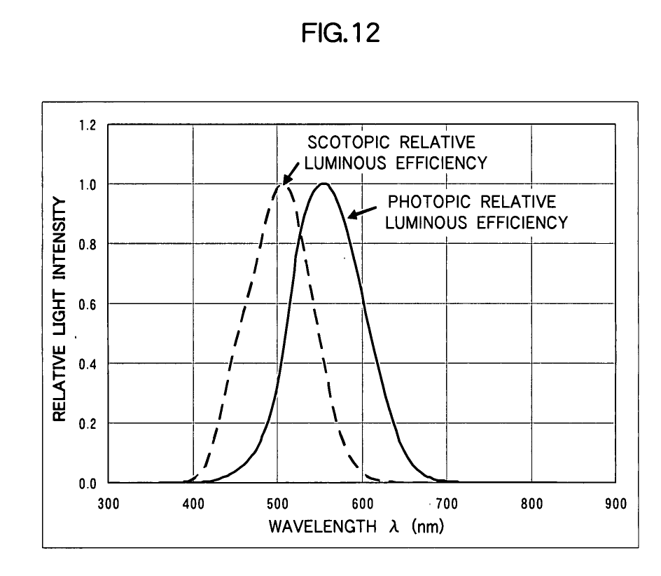

Human beings can sense light between approximately 380 and 780 nm, and the sensitivity of the eye to light varies depending on the wavelength of the light. In a well-illuminated environment, the human eye senses 550 nm light as the brightest, and in a poorly illuminated environment, the human eye senses 507 nm light as the brightest. The luminous efficiency of the human eye is typically represented by using a standard luminous efficiency curve as shown in FIG. 12. The horizontal axis shows the wavelength of the light, and the vertical axis shows the relative emission intensity. The value for the relative emission intensity shown in FIG. 12 is the luminous efficiency for each wavelength when the luminous efficiency at the wavelength perceived as brightest is normalized to 1. The curve shown with a solid line in FIG. 12 shows the standard luminous efficiency curve in a well-illuminated environment, i.e., the photopic relative luminous efficiency. The curve shown with a broken line shows the standard luminous efficiency curve for a poorly illuminated environment; i.e., the scotopic relative luminous efficiency.

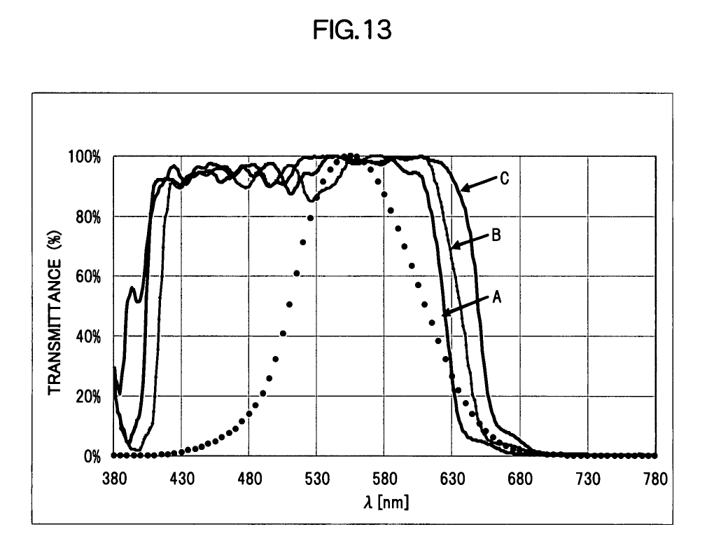

FIG. 13 is a graph that shows the wavelength dependence of the light transmittance of the interference filter 11. Curves A, B, C relate to the light transmittance for the interference filter 11. The changes in curves A through C result from varying the layer number of the dielectric thin film and the composition ratio of silicon and titanium in the dielectric thin film. The curve shown with a solid line in FIG. 13 corresponds to the photopic relative luminous efficiency. As shown in FIG. 13, the interference filter reflects light in the infrared range, and allows light in the visible range to pass through.

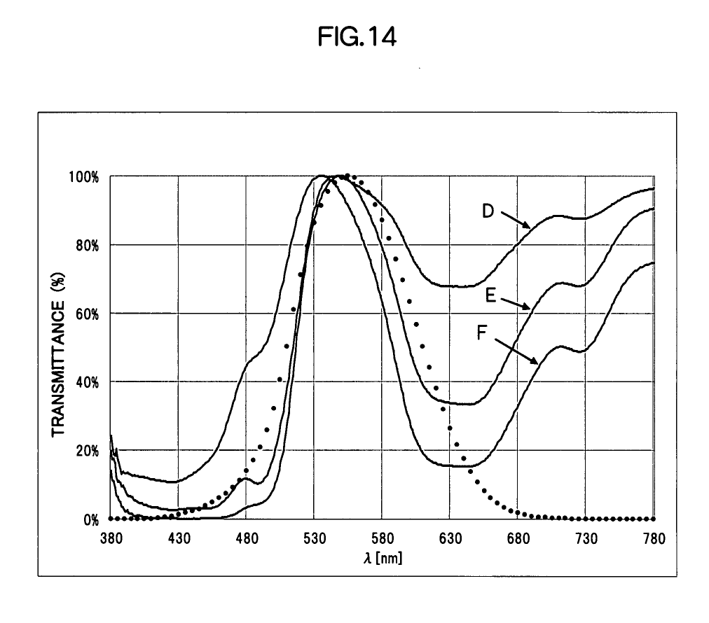

FIG. 14 is a graph that shows the wavelength dependence of the light transmittance of the color filter 8. Lines D, E, F show curves for the transmittance of the color filter 8. The changes in the curves D through F result from varying the materials in and the composition of the color filter 8. The curve shown with a broken line in FIG. 14 corresponds to the photopic relative luminous efficiency. The color filter 8 with light transmittance similar to the photopic relative luminous efficiency of the human eye in the visible light range can be formed by adjusting the ratio in which the materials in the color filter 8 are mixed. The color filter 8 allows not only light in the visible range to pass through, but infrared light as well. The photoelectric converter 1 matched to the luminous efficiency of the human eye can be formed by combining the color filter 8 and the interference filter 11 described above. Specifically, the external light that reaches the photoelectric converter 1 has the infrared light cut out by the interference filter 11 provided to the support base 21, and only light that matches the luminous efficiency of the human eye is allowed to pass through the color filter 8. It is therefore possible to create the photoelectric converter 1 adjusted to the luminous efficiency of the human eye.

In FIGS. 13 and 14, the interference filter 11 and the color filter 8 adjusted to the photopic relative luminous efficiency curve are shown. However, the invention according to the present embodiment is not limited to this arrangement. Specifically, the interference filter 11 and the color filter 8 adjusted to the scotopic relative luminous efficiency curve can also be used. It is accordingly possible to create a photoelectric converter adjusted to the luminous efficiency of the human eye in a poorly illuminated environment. In other words, various photoelectric converters tailored to specific applications can be formed by adjusting the wavelength dependence of the light transmittance of the interference filter 11 and the color filter 8.

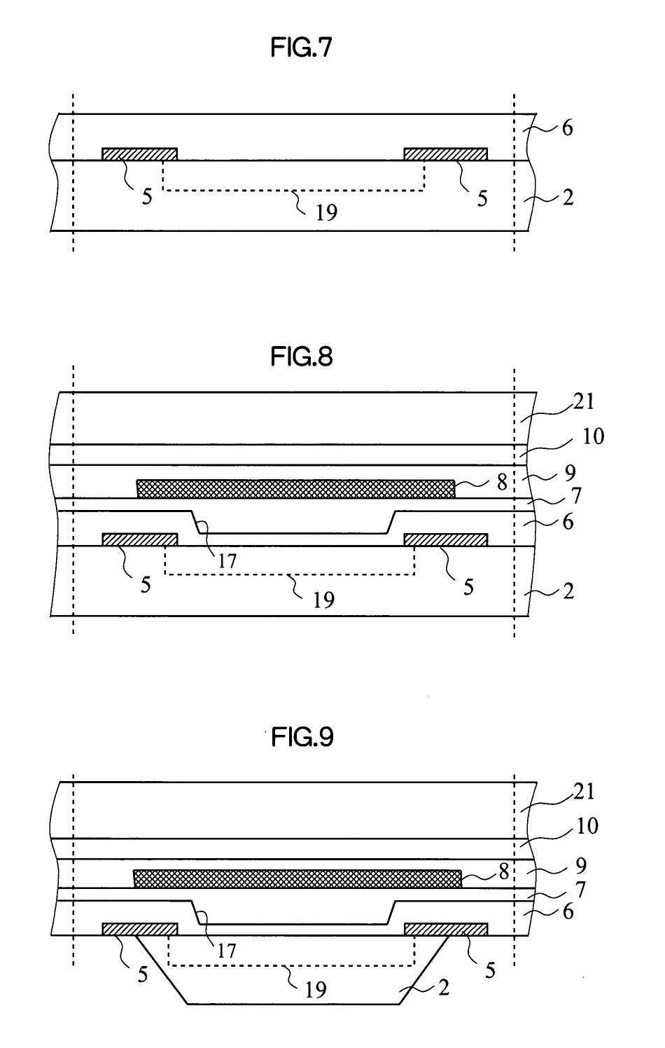

A description shall now be provided in regard to a method for manufacturing the photoelectric converter 1 according to the present embodiment of the invention. FIGS. 7 through 11 show cross-sectional structures of the photoelectric converter during each manufacturing step. The photoelectric converter 1 is manufactured through a step for forming a semiconductor integrated circuit 19 on each division of the semiconductor substrate marked off by scribe lines, a step for laminating each of the layers onto the semiconductor substrate and then dividing along the scribe lines, and a step for sealing the photoelectric converter 1 in a chip-sized package. The manufacturing steps are described in detail below.

The semiconductor integrated circuit 19 comprising a PN junction on the surface of the semiconductor substrate 2 is formed. The internal wiring 5 is formed on the semiconductor substrate 2 in order to extract to the exterior electrical information based on light received and photoelectrically converted by PN junction. The insulation film 6 is formed on the internal wiring 5 (FIG. 7). The insulation film 6 can, for instance, be a silicon oxide film.

The aperture 17 is formed on the insulation film 6 in correspondence with the light-receiving area where the photoelectric converter 1 receives light. Here, one rectangular aperture 17 is formed for the photoelectric converter 1. Spin coating or another method is used to create the smoothing film 7, which comprises an acrylic resin or other resin transparent to light on the insulating layer 6 on which the aperture 17 is formed. On the smoothing film 7, the color filter 8, which has a transparent spectrum adjusted for luminous efficiency, is formed in the region above the island-shaped semiconductor substrate 2 which will be formed later. The color filter 8 is worked into a specific shape using photolithography or etching after being formed on the whole surface of the semiconductor substrate 2 by spin coating or another method. The thickness of the color filter 8 can be made uniform by creating the color filter 8 on the smoothing film 7 that smoothes the irregularities formed by the internal wiring 5 or the like. The second protective film 9, which is transparent to visible light and made of acrylic resin, is formed on the color filter 8 using spin coating or another method. The resin layer 10 made of an epoxy or the like is formed on the second protective layer 9. The adhesion between the color filter 8 and the resin layer 10 is increased by forming a resin layer 10 on the color filter 8 with the second protective layer 9 provided therebetween. The support base 21, including the interference filter 11, is formed on the resin layer 10 (FIG. 8).

The semiconductor substrate 2 is etched on the side without the support base 21; i.e., on the back of the substrate 2, and the island-shaped semiconductor substrate 2 is formed so that the internal wiring 5 is exposed (FIG. 9). For instance, when a silicon substrate is used as the semiconductor substrate 2, chemical etching using hydrofluoric acid, acetic acid, or another mixture can be used to perform the etching thereon. The thickness of the semiconductor substrate 2 is ideally also reduced through mechanical polishing prior to chemical etching.

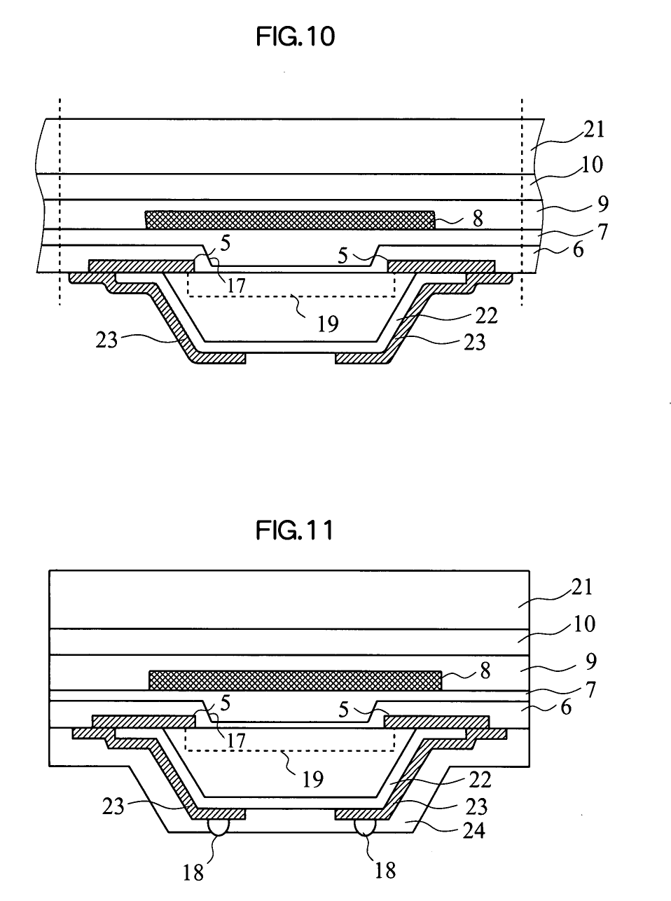

An insulating layer 22 is formed so that all of the semiconductor substrate 2, formed by etching and in the shape of an island, is covered. The insulating layer 22 is formed so that only a part of the exposed internal wiring 5 is covered. In other words, the insulating layer 22 is formed so that a part of the internal wiring 5 is left in an exposed state. An external wiring 23 connected to the internal wiring 5 and used to output an electrical signal to the exterior is then formed below the insulating layer 22. The external wiring 23 is formed in correspondence with the internal wiring 5 (FIG. 10). One end of the external wiring 23 is in contact with the exposed part of the internal wiring 5.

A solder ball 18, which is the connecting terminal for connecting the photoelectric converter 1 to the external elements, is formed in the vicinity of the other end of the external wiring 23 where the internal wiring 5 is not in contact with the external wiring 23. The solder ball 18 can be formed by using heat to reflow the ball-shaped solder material. A passivation film 24 is formed on the back of the semiconductor substrate 2 so that a portion of the solder ball is exposed and the entire semiconductor wafer is covered. The passivation film 24 can prevent damage due to physical shock to the semiconductor substrate 2 and the external wiring 23. After the passivation film 24 is formed, cutting is performed along the scribe lines. The photoelectric converters 1 are separated one another by the cutting using a dicing saw, and the photoelectric converter 1 used in a chip-sized package is formed (FIG. 11).

As described above, infrared light is reflected using the interference filter 11, which comprises a multilayer dielectric film, without using a resin that absorbs infrared light. As a result, light attenuation can be minimized, and light usage efficiency increased. The color filter 8, which has a light transmittance close to the luminous efficiency of the human eye, is provided, thereby allowing the photoelectric converter 1 adjusted for the luminous efficiency of the human eye to be provided. In other words, according to the present invention, it is possible to obtain a photoelectric converter having improved light usage efficiency and infrared light cut out. A photoelectric converter having sensitivity close to the luminous efficiency of the human eye can be obtained by providing a color filter having light transmittance characteristics close to the luminous efficiency of the human eye.

What is claimed is:

1. A photoelectric converter, comprising:
a semiconductor substrate on which at least one photoelectric conversion element is formed;
a color filter provided on the semiconductor substrate; and
a support base bonded to the color filter; wherein
the support base has an interference filter that is comprised of multiple thin layers of dielectric material and that reflects infrared light.

2. The photoelectric converter of claim 1, wherein
the support base is bonded to the semiconductor substrate using a resin that absorbs infrared light.

3. The photoelectric converter of claim 1, wherein
a plurality of the interference layers are laminated in the support base.

4. The photoelectric converter of claim 1 wherein
the color filter has a transmittance spectrum adjusted to a luminous efficiency of a human eye.
